(19) United States
(12) Patent Application Publication
(10) Pub. No.: US 2026/0363032 A1
(43) Pub. Date: Nov. 12, 2026

(54) PHOTOPATTERNABLE INORGANIC NANOPARTICLE HARDMASK

(71) Applicant: NanoPattern Technologies, Inc., Chicago, IL (US)

(72) Inventors: Danielle Russell Chamberlin, Belmont, CA (US); Yu Kambe, Menlo Park, CA (US); Forrest Samuel Etheridge, Oak Park, IL (US); Marissa Michelle Tranquilli, Chicago, IL (US); Rui Peng, Naperville, IL (US); Mehr Unnisa Zaheer, Chicago, IL (US); Alexis Miranda, Mount Prospect, IL (US)

(21) Appl. No.: 19/320,817

(22) Filed: Sep. 5, 2025

Related U.S. Application Data
(60) Provisional application No. 63/802,076, filed on May 8, 2025.

(51) Int. Cl. H10P 76/20; G03F 7/004; G03F 7/32; G03F 7/40; H10P 50/00; H10W 20/00

(52) U.S. Cl. CPC H10P 76/2041; G03F 7/0041; G03F 7/0042; G03F 7/32; G03F 7/40; H10P 50/73; H10W 20/086

(57) ABSTRACT

The present invention provides a photopatternable nanoparticle hardmask which may be used for high-resolution patterning in advanced semiconductor packaging. The hardmask composition includes nanoparticles and photoacid generators which react upon exposure to light to cause crosslinking between nanoparticles in the exposed area. The photopatterned nanoparticle hardmask layer may be developed with, for example, deionized water. The nanoparticle hardmask layer is subsequently annealed to reduce porosity and create a hard mask layer resistant to dry etching. The nanoparticle hardmask layer and developer work like a conventional negative photoresist and enable 1-micron resolution trench patterns in glass, polymer dielectrics, or compound semiconductors with reduced processing steps and improved throughput. The invention also describes methods for applying and developing the nanoparticle hardmask layer in semiconductor manufacturing.

### CROSS-REFERENCE TO RELATED APPLICATIONS

This application claims benefit of priority to U.S. Provisional Patent Application 63/802,076 filed May 8, 2025, which is incorporated herein by reference in its entirety.

### FIELD OF THE INVENTION

The present invention relates to the field of semiconductor manufacturing, specifically to the development of photopatternable inorganic nanoparticle hardmasks for high-resolution patterning and etching for advanced packaging applications.

### BACKGROUND

The semiconductor industry urgently needs advancements in RDL (redistribution layer) technology to keep pace with the increasing miniaturization and complexity of 2.5 D/3 D packaging, as Artificial Intelligence, flexible systems, and hybrid electronics demand higher performance. RDLs must achieve higher resolutions to support greater interconnect densities and enhanced electrical performance. Current manufacturing processes are unable to achieve resolutions below 20 micrometers and rely on high temperature/vacuum deposition and plasma etch steps, limiting precision, material choice, and throughput. Both fan-in and fan-out RDLs are affected, leading to slow fulfillment and increased production costs.

### SUMMARY

This specification discloses photopatternable inorganic nanoparticle hardmasks and methods for making and using them, for example in semiconductor device microelectronic structure manufacturing. The term “nanoparticle” is used herein to refer to particles having a diameter or maximum dimension of, for example, less than or equal to about 10 microns, less than or equal to about 5 microns, less than or equal to about 1 micron, less than or equal to about 500 nm, less than or equal to about 100 nm, or less than or equal to about 50 nm.

In one embodiment of the invention, a method of forming a microelectronic structure comprises providing a substrate having a surface that is optionally coated with one or more additional layers, applying a hardmask composition comprising inorganic nanoparticles and a photoacid generator to the substrate surface or to an outermost surface of the one or more additional layers to form a hardmask layer, exposing the hardmask layer to patterned (e.g., violet or ultraviolet) light to yield exposed and unexposed portions of the hardmask layer, contacting the exposed and unexposed portions of the hardmask layer with a developer to remove the unexposed portions of the hardmask layer to provide a patterned hardmask layer comprising one or more openings, and, after removing the unexposed portion of the hardmask layer, annealing the patterned hardmask layer to increase its density to above 65% volume percent solid to provide a dense patterned hardmask layer comprising one or more openings through which underlying material may be etched.

The nanoparticles may be, for example, greater than or equal to 50%, 60%, 70%, 80%, 90%, or 99% by weight of the hardmask layer, for example about 90% to 99% by weight of the hardmask layer.

The hardmask layer may optionally comprise polymeric (e.g., organic polymeric) material, if so at less than or equal to about 10% by weight.

In any of the above variations, the nanoparticles may be, for example, nanoparticles of ZrO₂, SiO₂, HfO₂, TiO₂, or Al₂O₃, or a mixture of any combination of ZrO₂, SiO₂, HfO₂, TiO₂, and Al₂O₃ nanoparticles.

The dense patterned hardmask layer may have a dielectric constant <12 from 10k Hz to 60 GHz, for example.

In any of the above variations, the nanoparticles may be crystalline, amorphous, or a mixture of crystalline and amorphous nanoparticles.

In any of the above variations, the nanoparticles may have a size range (diameter, or largest dimension) of, for example, about 3 nm to about 50 nm, about 5 nm to about 50 nm, or about 10 nm to about 50 nm.

In any of the above variations, the photoacid generator may be, for example, 1% to 10%, 1% to 20%, 1% to 30%, 1% to 40%, 1% to 50%, less than or equal to 1%, less than or equal to 10%, less than or equal to 20%, less than or equal to 30%, less than or equal to 40%, or less than or equal to 50% by weight of the hardmask layer.

In any of the above variations, the photoacid generator may be or comprise, for example, 1-Diazo-2-naphthol-4-sulfonic acid (DNS); 2-diazo-1-naphthol-4-sulfonic acid (2-DNS), 2-diazo-1-naphthol-4-sulfonyl chloride (DNQ-Cl); 4-(1-methyl-1-phenylethyl)-phenyl 3-diazo-3,4-dihydro-4-oxo-1-naphthalenesulfonate (DNQ-Ar); photoacid generator/anion mixtures and non-ionic photoacid generators disclosed in U.S. Pat. No. 11,720,017, U.S. Patent Publication 2023/0341770, or U.S. Patent Publication 2022/0011664; or mixtures thereof. Ligand systems (which are not photoacid generators) disclosed in U.S. Patent Publication 2023/0313030 may also or alternatively be used. U.S. Pat No. 11,720,017, U.S. 2023/0341770, U.S. 2022/0011664, and US 2023/0313030 are incorporated herein by reference for their disclosure cited in this paragraph.

In any of the above variations, the hardmask composition applied to form the hardmask layer may comprise a solvent, for example a high dielectric constant solvent such as, for example, gamma butyrolactone or mixtures of gamma butyrolactone and one or more other suitable solvents such as dimethyl sulfoxide, for example. Alterative solvents may also include ethyl lactate, ethylene glycol, propylene glycol, acetonitrile, m-cresol, cyrene, propylene carbonate, or mixtures thereof. The hardmask composition applied to form the hardmask layer may also comprise water as a solvent. Additionally, isopropyl alcohol and ethylene glycol or propylene glycol may be added to an aqueous solvent mixture. Suitable solvents may also include, for example, dimethylformamide (DMF), chlorobenzene, toluene, propylene glycol monomethyl ether acetate (PGMEA), heptane, hexane, methyl ethyl ketone (MEK), butyl acetate, 2-propanol, methanol, and ethanol, or mixtures thereof.

In any of the above variations, the developer may be aqueous based. The developer may be an aqueous 1-10 weight percent Tetramethylammonium hydroxide solution, for example. The developer may be or comprise deionized water, for example. Alternatively, the developer may be or comprise organic material.

In any of the above variations, the optional one or more additional layers may comprise a dielectric layer. The dielectric layer may be or comprise, for example, a (e.g., inorganic) glass or a polymer. Such polymer may be or comprise, for example, a polyimide, a benzocyclobutene, or a polybenzoxazoles. The dielectric material may be or comprise other organic materials including, but not limited to, spin-on carbon materials. Any suitable dielectric material may be used.

For clarity, the hardmask layer need not be deposited on a dielectric layer. In addition to the dielectric materials previously listed, the hardmask layer may be deposited on any other suitable material including, for example, silicon, silicon dioxide, glass, silicon nitride, gallium nitride, and other III-V materials.

In any of the above variations in which the one or more additional layers comprises a layer of dielectric material, the method may comprise (e.g., in a single damascene method) etching the dielectric layer through the one or more openings in the dense patterned hardmask layer to pattern the dielectric layer with one or more trenches, vias, or any combination of trenches and vias. The one or more trenches, vias, or any combination of trenches and vias may have, for example, minimum lateral widths in a plane of the dielectric layer greater than 0.0 microns and less than or equal to 5.0 microns and depths perpendicular to the plane of the dielectric layer greater than or equal to 2.0 microns. Any suitable wet or dry (e.g., O₂ plasma or CF₄) etch process may be used.

After etching the dielectric layer through the openings in the dense patterned hardmask layer to pattern the dielectric layer, the dense patterned hardmask layer may optionally be removed or retained on the dielectric layer. The one or more trenches, vias, or any combination of trenches and vias may then be filled with metal, for example by electroplating on a previously deposited seed layer. The metal may be or comprise copper, for example.

Alternatively, in another variation, prior to etching the dielectric layer through the openings in the dense patterned hardmask layer the method may comprise (e.g., in a dual damascene method) disposing a dielectric layer on the dense patterned hardmask layer, applying a hardmask composition comprising inorganic nanoparticles and a photoacid generator to the dielectric layer on the dense patterned hardmask layer to form a second hardmask layer, exposing the second hardmask layer to patterned light to yield exposed and unexposed portions of the second hardmask layer, contacting the exposed and unexposed portions of the second hardmask layer with a developer to remove the unexposed portions of the second hardmask layer to provide a second patterned hardmask layer comprising one or more openings overlapping the one or more openings in the underlying dense patterned hardmask layer; and, after removing the unexposed portion of the second hardmask layer, annealing the second patterned hardmask layer to increase its density to above 65% volume percent solid to provide a second dense patterned hardmask layer comprising openings through which the dielectric layers may be etched.

The composition of the dielectric layer disposed on the dense patterned hardmask layer may be, for example, as described above for dielectric layers. The hardmask composition with which the second hardmask layer is formed may, for example, comprise nanoparticles and photogenerators as described above for hardmask compositions. The developer used to develop the second hardmask layer may be, for example, a developer as described above.

The method may comprise etching the dielectric layers through the openings in the second dense patterned hardmask layer and the openings in the underlying dense patterned hardmask layer to pattern the dielectric layers with, for example, one or more trenches, vias, or any combination of trenches and vias. The one or more trenches, vias, or any combination of trenches and vias may have, for example, minimum lateral widths in a plane of the dielectric layer greater than 0.0 microns and less than or equal to 5.0 microns, or less than or equal to 1.0 micron. The one or more trenches, vias, or any combination of trenches and vias may have, for example, depths perpendicular to the plane of the dielectric layer greater than or equal to 2.0 microns. Any suitable wet or dry (e.g., O2 plasma) etch process may be used.

After etching the dielectric layers through the openings in the second dense patterned hardmask layer and the openings in the underlying dense patterned hardmask layer, the second dense patterned hardmask layer may optionally be removed or retained. The one or more trenches, vias, or any combination of trenches and vias may then be filled with metal, for example by electroplating on a previously deposited seed layer. The metal may be or comprise copper, for example.

In another embodiment of the invention, a semiconductor structure comprises a semiconductor substrate, a dielectric layer disposed on the semiconductor substrate or on one or more additional layers disposed on the semiconductor substrate, and a dense patterned hardmask layer disposed on the dielectric layer, the hardmask layer comprising greater than or equal to 60% by weight inorganic nanoparticles, having a density greater than or equal to 65% volume percent solid, and comprising one or more openings through which the dielectric layer may be selectively etched.

The dense patterned hardmask layer comprises no more than 10% by weight polymeric (e.g., organic polymeric) material.

The nanoparticles may be, for example, nanoparticles of ZrO₂, SiO₂, HfO₂, TiO₂, or Al₂O₃, or a mixture of any combination of ZrO₂, SiO₂, HfO₂, TiO₂, or Al₂O₃ nanoparticles.

In any of the above variations, the nanoparticles may be crystalline, amorphous, or a mixture of crystalline and amorphous nanoparticles.

The dense patterned hardmask layer may have a dielectric constant <12 from 10k Hz to 60 GHz, for example.

In any of the above variations, the nanoparticles may have a size range (diameter, or largest dimension) of, for example, about 3 nm to about 50 nm, about 5 nm to about 50 nm, or about 10 nm to about 50 nm.

In any of the above variations, the dielectric layer may be or comprise, for example, a (e.g., inorganic) glass or a polymer. Such polymer may be or comprise, for example, a polyimide, a benzocyclobutene, or a polybenzoxazoles. The dielectric layer may be or comprise other organic materials including, but not limited to, spin-on carbon materials. Any suitable dielectric material may be used.

The photopatternable inorganic nanoparticle hardmask layers and methods for making and using them described herein provide various advantages compared to prior art. For example, these photopatternable hardmasks may enable the fabrication of 1.0 micron resolution trenches in dielectric materials enabling applications in displays, semiconductor packaging, and flexible electronics. In addition, they may be used for panel level processing instead of wafer level processing, allowing for larger, rectangular areas to be processed and enabling lower cost fabrication.

Further advantages include that photopatternable hardmasks as described herein may work with low thermal budgets (150 °C), be compatible with i-line, g-line, and h-line lithography systems, serve as a leave-in hardmask not needing removal, and provide strong etch contrast for various dielectric polymers and glasses.

Use of the photopatternable hardmasks can increase interconnect density for enhanced performance, lower latency, increased bandwidth, and improved power efficiency. If used as a leave-in resist it can eliminate extra bottlenecks in semiconductor device development.

Both flexible and hybrid electronics will require RDLs and interconnects. While lower resolution RDLs can be made with photosensitive polyimide, the next generation of flexible electronics demands the patterning of various flexible and stretchable dielectric materials. The high-resolution, low temperature, etch mask solution using photopatternable inorganic nanoparticle hardmasks as described herein allows for the fabrication of RDLs and interconnects using a broader range of materials, including PET, PDMS, polyimide, and polyurethane. This flexibility in material choice, without the need to convert the materials into photosensitive polymers, is a significant value-add for the flexible and hybrid electronics community. Furthermore, oxides such as ZrO₂ have a strong etch resistance to solution-based etchers such as HF acid solution in comparison to glass. The photopatternable hardmask can therefore improve resolution and reduce steps in applications for hybrid electronics using glass core applications.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a flowchart that outlines a method for forming a photopatterned inorganic nanoparticle hardmask which may be used, for example, in a method for making a microelectronic structure as described in greater detail herein.

FIGS. 2, 3, 4, 5, 6, 7, 8, 9, 10, 11, 12, and 13 schematically illustrate intermediate and final structures in an example single damascene process employing a method as outlined in the flowchart of FIG. 1.

FIGS. 14, 15, 16, 17 and 18 schematically illustrate intermediate and final structures in an example dual damascene process employing a method as outlined in the flowchart of FIG. 1.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention. As used in this specification and the appended claims, the singular forms “a,” “an,” and “the” include plural referents unless the context clearly indicates otherwise.

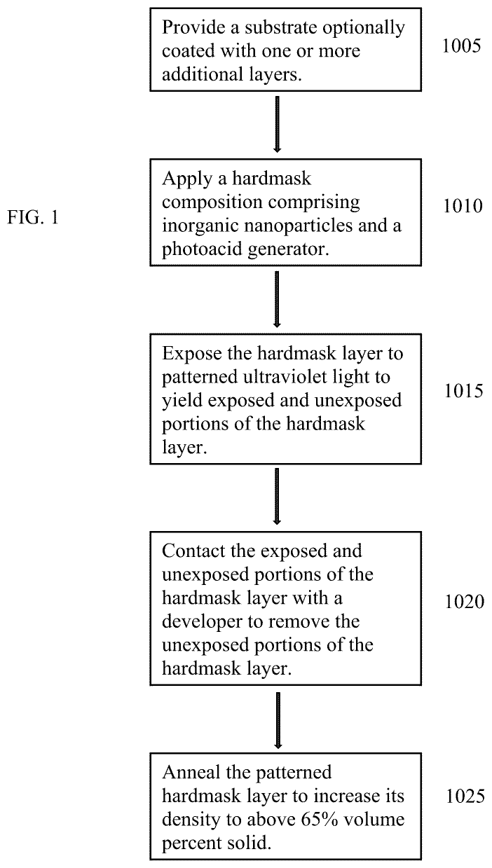

FIG. 1 shows a flowchart that outlines a method for forming a photopatterned inorganic nanoparticle hardmask which may be used, for example, in a method for making a microelectronic structure. The inorganic nanoparticle hardmask acts as a negative photoresist in the photopatterning portions of the methods. As understood in the art, a negative photoresist is a photoresist in which the portion of the photoresist that is exposed to light becomes insoluble in the photoresist developer. The unexposed portion of the photoresist is dissolved by the photoresist developer.

As further explained below, the inventors have determined that a photopatternable inorganic nanoparticle hardmask as described herein may be made significantly more effective by annealing the developed patterned inorganic nanoparticle hardmask prior to using it as an etch stop in patterning an underlying (e.g., dielectric) layer. Annealing the developed patterned inorganic nanoparticle hardmask makes it denser and less porous, for example by sintering the inorganic nanoparticles. This makes the patterned inorganic nanoparticle hardmask less permeable to the (e.g., plasma) etch process and thereby provides a greater etch contrast between the dense hardmask and the underlying layer being etched through patterned openings in the dense hardmask.

As used herein, the term “anneal” refers to heating and subsequently cooling the developed patterned inorganic nanoparticle hardmask without specifying any particular temperature versus time profile. That is, as used herein the term annealing includes temperature versus time profiles in which the developed patterned hardmask is cooled more slowly than it was heated but does not require such a temperature versus time profile. Any suitable heating and cooling temperature versus time profile and any suitable temperatures may be used.

Referring again to the method outlined in FIG. 1, step 1005 provides a substrate having a surface that is optionally coated with one or more additional layers. The substrate may be or comprise a semiconductor (e.g., crystalline silicon) substrate, for example. Any suitable substrate may be used. The one or more additional layers may be or comprise, for example, one or more dielectric layers. Such one or more dielectric layers may comprise, for example, any of the dielectric materials described above in the summary as suitable for the dielectric layer.

Step 1010 applies a hardmask composition comprising inorganic nanoparticles and a photoacid generator to the substrate surface or to an outermost surface of the one or more additional layers to form a hardmask layer. The hardmask composition comprises inorganic nanoparticles and photoacid generators at, for example, any of the weight percent ranges described above in the summary. The hardmask composition may optionally include a small percentage of stabilizers. The nanoparticles may be, for example, any of the nanoparticles described above in the summary. The nanoparticles may have size ranges, for example, as described above in the summary. The photoactive compounds and stabilizers may comprise, for example, any of the photoacid generators or photoactive ligand materials described above in the summary.

The hardmask composition may be formed by dispersing the nanoparticles, the photoactive compounds, and the (optional) stabilizers in a solvent to form a mixture. Suitable solvents may include, for example, any of the solvents and solvent mixtures described above in the summary.

The hardmask composition may be applied using, for example, spin coating, slot die coating, slit coating, or blade coating methods. The hardmask composition may be applied to form a layer having a thickness perpendicular to the layer of, for example, of about 20 nm to about 500 nm.

Step 1015 exposes the hardmask layer to patterned (e.g., violet or ultraviolet) light to yield exposed and unexposed portions of the hardmask layer. The hardmask layer may be photopatterned with light having a wavelength of, for example, about 195 nm to 420 nm (e.g., 365 nm or 405 nm) with a dosage of, for example, about 80 mJ/cm² to about 1000 mJ/cm², and capable of achieving 1-micron resolution patterns.

Step 1020 contacts the exposed and unexposed portions of the hardmask layer with a developer to remove the unexposed portions of the hardmask layer to provide a patterned hardmask layer comprising one or more openings. The hardmask layer may be developed with, for example, deionized water, aqueous 0.1%-10% by weight tetramethylammonium hydroxide, PGMEA, heptane, hexane, alcohol, MEK, butyl acetate, ethyl lactate, ethylene carbonate, propylene carbonate, or a mixture thereof. Additional surfactants, for example pluronic surfactants, may be added to the developer to aid in removal of the unexposed portions. The developed patterned dry layer may be rinsed, for example, with deionized water.

Step 1025 anneals the developed patterned hardmask layer to increase its density to above 65% volume percent solid to provide a dense patterned hardmask layer comprising one or more openings through which underlying material may be selectively etched. During the annealing step the developed patterned hardmask layer may be heated to a maximum temperature of about 200 °C to about 450 °C for example. The annealing step may have a duration of about 2 minutes to about 30 minutes, for example,

In an investigation of the effect of the annealing step, the inventors formed a ZrO₂ nanoparticle hardmask layer according to the method described above and measured its refractive indices at 632.8 nm using ellipsometry before and after annealing. Prior to annealing, the ZrO₂ nanoparticle hardmask layer had a refractive index of 1.62, which is 54% of the bulk ZrO₂ refractive index. This indicates that prior to annealing the ZrO₂ nanoparticle hardmask layer had a density of about 54% volume percent solid. After annealing, the ZrO₂ nanoparticle hardmask layer had a refractive index of 1.77, which is 67% of the bulk ZrO₂ refractive index. This indicates that after annealing the ZrO₂ nanoparticle hardmask layer had a density of about 67% volume percent solid.

As described in the example section below, the inventors have found that annealed photopatterned inorganic nanoparticle hardmasks prepared as described above may have an etch contrast with polyimide using O₂ plasma of, for example, 100 to 3000 or better.

As noted above, the method described above with respect to FIG. 1 for forming a photopatterned inorganic nanoparticle hardmask may be employed in methods for making microelectronic structures. Single and dual damascene microelectronic structure manufacturing methods employing the method outlined in FIG. 1 are described next.

### Single Damascene Method

FIGS. 2-13 schematically illustrate intermediate and final structures in an example single damascene process employing a method a method for forming a photopatterned inorganic nanoparticle hardmask as described above with respect to the flowchart of FIG. 1.

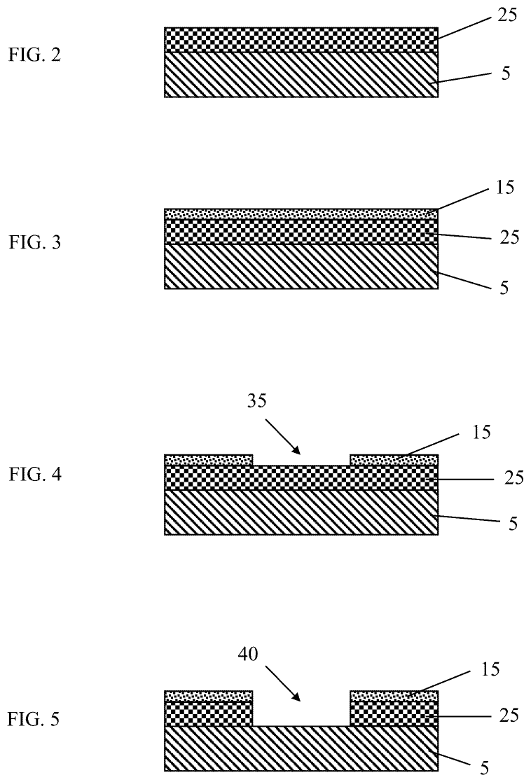

FIG. 2 shows a dielectric layer 25 disposed by conventional methods on a semiconductor wafer 5. In FIG. 3 an inorganic nanoparticle hardmask composition layer 15 as described above is applied to dielectric layer 25.

Next, layer 15 is illuminated with patterned (e.g., violet or ultraviolet) light and then developed as described above to form a patterned inorganic nanoparticle composition hardmask layer comprising one or more openings 35 as shown in FIG. 4. The patterned inorganic nanoparticle composition hardmask layer is then annealed as described above to increase its density to above 65% volume percent solid to provide a dense patterned inorganic nanoparticle hardmask layer comprising one or more openings 35 through which the underlying dielectric layer 25 may be selectively etched.

Next, dielectric layer 25 is etched through opening 35 in dense hardmask layer 15 to form an opening 40 in dielectric layer 25 as shown in FIG. 5. The opening may be, for example, in the form of a vertical via or in the form of a trench (e.g., for a wire) running perpendicular to the sheet of the drawing in the plane of dielectric layer 25. Any suitable etch process may be used, for example an O₂ plasma etch, an inductively coupled plasma (ICP), or a wet etch (e.g., KOH solution).

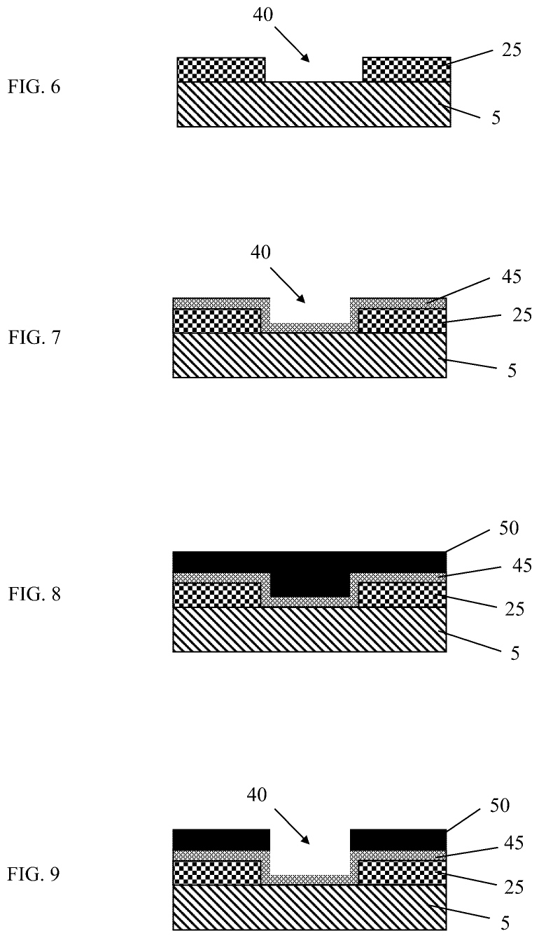

As shown in FIG. 6, after etching dielectric layer 25 the remaining portions of dense patterned inorganic nanoparticle hardmask layer 15 may be stripped, for example with a dilute acid solution such as dilute (<1%, e.g. 0.1%) HF or a buffered oxide etch solution. In addition to wet etch, dry etch provides another avenue to remove the residual hardmask. A combination of CF₄ and O₂ plasma or CF₄ and Ar plasma can efficiently etch the hardmask. Alternatively, the remaining portions of dense patterned inorganic nanoparticle hardmask layer 15 may be retained in the structure, particularly if dense patterned inorganic nanoparticle hardmask layer 15 has a dielectric constant less than about 12 and/or is thinner than about 100 nm.

Next, as shown in FIG. 7 a conventional seed layer 45 (to support electroplating) is deposited on the structure of FIG. 6. Seed layer 45 may comprise, for example, sputtered Au on sputtered Cr. Any suitable seed layer may be used.

Next, as shown in FIG. 8, layer 50 of conventional photoresist is deposited over seed layer 45 and in opening 40. Any suitable conventional photoresist may be used.

Next, as shown in FIG. 9, layer 50 of conventional photoresist is conventionally photopatterned and developed to reopen opening 40 and expose portions of seed layer 45 in opening 40.

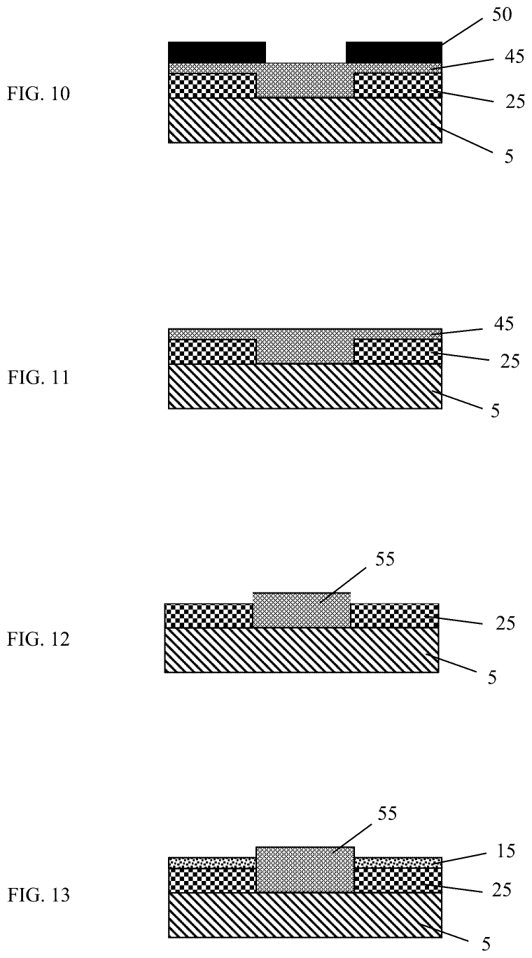

Next, as shown in FIG. 10, metal (e.g., copper) is conventionally electroplated onto the exposed portions of seed layer 45 to fill opening 40.

Next, as shown in FIG. 11, the remaining portions of conventional photoresist 50 are conventionally stripped using any suitable stripping process.

Next, as shown in FIG. 12, remaining exposed portions of seed layer 45 are removed using any suitable conventional etching process, to provide a structure comprising a metal feature 55 (e.g., wire or via) in dielectric layer 25 on wafer 5. FIG. 13 shows the similar structure that would have resulted had dense patterned inorganic nanoparticle hardmask layer 15 been retained in the structure (FIG. 5) rather than stripped (FIG. 6).

The structures shown in FIG. 12 and FIG. 13 may be, for example, portions of an RDL layer, an interposer layer, or an interconnect layer.

### Dual Damascene Method

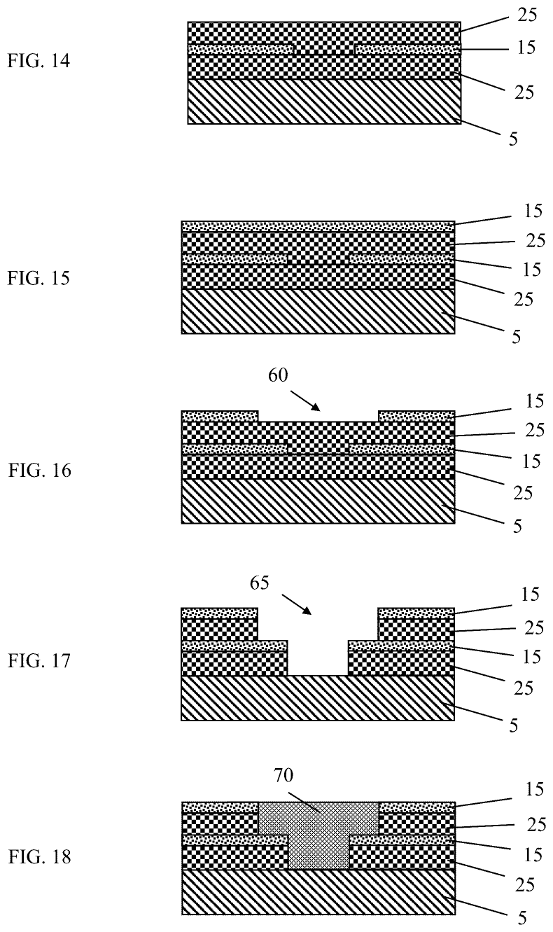

FIGS. 14, 15, 16, 17 and 18 schematically illustrate intermediate and final structures in an example dual damascene process employing a method for forming a photopatterned inorganic nanoparticle hardmask as described above with respect to the flowchart of FIG. 1. Some conventional steps and corresponding intermediate structures that were described or shown above with respect to a single damascene process, for example involving conventional photoresists and seed layers, are omitted from the following description for brevity.

Referring again to FIG. 4 as well as to FIG. 14, a second dielectric layer 25 is disposed by conventional methods on the structure shown in FIG. 4 to provide the structure shown in FIG. 14. Second dielectric layer 25 may have any of the compositions, thicknesses, and other properties described above for the dielectric layer 25 disposed in the stack earlier in the process. In the structure shown in FIG. 14, the two dielectric layers 25 may have the same or different compositions.

In FIG. 15 an inorganic nanoparticle hardmask composition layer 15 as described above is applied to the second dielectric layer 25. From the bottom to the top of the stack, the structure illustrated in FIG. 15 comprises wafer 5, a first dielectric layer 25, a dense patterned layer 15 of inorganic nanoparticle hardmask composition (patterned and annealed at earlier steps), a second dielectric layer 25, and a second layer 15 of inorganic nanoparticle hardmask composition (in this structure, not yet patterned and annealed).

Next, the second layer 15 of inorganic nanoparticle hardmask composition is illuminated with patterned (e.g., violet or ultraviolet) light, developed, and annealed as described above to form a dense patterned inorganic nanoparticle composition hardmask layer comprising one or more openings 60 exposing portions of the underlying second dielectric layer 25 as shown in FIG. 16. The one or more openings 60 overlap the one or more openings previously created in the first dielectric layer 25.

Next, the second dielectric layer 25 and the first dielectric layer 25 are etched through the openings in the second dense patterned inorganic nanoparticle composition hardmask layer 15 and the underlying dense patterned inorganic nanoparticle composition hardmask layer to form an opening 65 as shown in FIG. 17. The opening may be, for example, in the form of a vertical via, in the form of a trench (e.g., for a wire) running perpendicular to the sheet of the drawing in the plane of dielectric layer 25, or overlap a via with a trench. Any suitable etch process may be used, for example an O₂ plasma etch, an inductively coupled plasma (ICP), or a wet etch (e.g., HF acid solution).

Next, a metal (e.g., copper) is conventionally electroplated (e.g., using a series of steps as described above but partially omitted here) to fill opening 65 and provide a structure comprising a metal feature 70 (e.g., wire, via, or wire and via) as shown in FIG. 18. The remaining portions of the second dense patterned inorganic nanoparticle composition hardmask layer 15 may be retained in the structure or optionally be stripped prior to or after the electroplating process.

The structure shown in FIG. 18 may be a portion of an RDL layer, an interposer layer, or an interconnect layer for example.

### Example 1: Preparation, Application, Patterning, Development of Nanoparticle Hardmask

Properties of nanoparticles: ZrO₂ amorphous nanoparticles 5 nm-50 nm in diameter with ethylene glycol-based ligands on the surface in PGMEA from Sigma, or ZrO₂ amorphous nanoparticles 10 nm-50 nm in diameter with H+ passivation in water crashed and redispersed in DMF.

Formulation of hardmask composition: dissolve 1-DNS in DMF 50 mg/ml, mix nanoparticle dispersion with 1-DNS solution so that the coated film would have 5 weight percent of PAG and 95 weight percent of ZrO₂.

Application Process: the formulation is spin coated, blade coated, or slot die coated onto a (e.g., polyimide) substrate.

Patterning: the photopatterning process may use UV or other suitable light sources, for example 365 nm light at 100 mJ/cm² to 400 mJ/cm².

Development: the photopatterned hardmask composition film may be (soft) baked, for example at 110 C for 30 seconds to fix the pattern. The patterned hardmask composition film may be developed with deionized water or an aqueous TMAH solution, then rinsed with deionized water.

Annealing: the developed patterned hardmask composition film is annealed to increase its density, e.g. by at least partially sintering the nanoparticles. This improves etch selectivity.

### Experimental Results

Method The dimethylformamide dispersed ZrO₂ was prepared over the course of 2 days in a 3 step washing process. 5 mL aqueous ZrO₂ nanoparticles (300 mg/mL) was first crashed with 30 mL of acetone and mixed for 30 minutes. The crashed mixture was then centrifuged at 2500 rpm acceleration for 15 minutes. The supernatant was decanted, and the pellet redispersed in 8 mL of dimethyl formamide. The mixture was stabilized overnight. For the second washing step, the ZrO₂ mixture was further crashed with 30 mL of toluene and allowed to mix for 30 minutes. The same centrifuge process was repeated: the crashed mixture was centrifuged at 2500 rpm acceleration for 15 minutes, and the supernatant was decanted. Third and lastly, the ZrO₂ pellet was washed with hexane to remove swelling from the toluene wash. 30 mL of hexane was added to the pellet and allowed to mix for 30 minutes to fully expose the ZrO₂ to the hexanes. After mixing, the centrifuge process was repeated: the crashed mixture was centrifuged at 2500 rpm acceleration for 15 minutes. The supernatant was decanted, and the pellet redispersed in 7.5 mL of dimethyl formamide, such that the final concentration of ZrO₂ is 200 mg/mL. The mixture was stabilized overnight, and the concentration was confirmed before use.

1-DNS was dissolved in DMF at 50 mg/mL, then 3 mL of nanoparticle solution was mixed with 3 mL of the 1-DNS solution and mixed overnight.

The hard mask mixture of nanoparticle solution and 1-DNS solution was spin coated, blade coated, or slot die coated onto a polyimide film substrate.

The nanoparticle hardmask composition film was exposed with patterned 365 or 375 nm light at 200-1020 mJ/cm², then baked in air at 70 °C for 30 seconds, then developed in 2.5 weight percent TMAH or deionized water with the assistance of bath sonication for 5 min, then rinsed in deionized water, then dried in N₂. The patterned film was annealed at 200 °C for 2 min prior to the etching steps to increase the density of the patterned film.

The dense patterned nanoparticle hardmask composition film and the portions of the underlying polyimide substrate exposed by the patterned openings in the dense nanoparticle hardmask composition film were etched in a CF₄ and O₂ plasma chamber using the following parameters: 7 sccm of CF₄, 33 sccm of O₂, 100 W RF Forward Bias Power, 20 Pa process pressure, for 5 minutes.

Results: The illumination pattern on the nanoparticle hardmask composition film consisted of 25 microns, 10 microns, and 5 microns squares. The patterning results observed by imaging show sub 10 microns lateral resolution, which may be further optimized. The thickness of the nanoparticle hardmask composition film was determined to be tunable from 70±5 to 100±10 nm with various spin rates by using stylus profilometry on the patterned ZrO₂ film. After the CF₄/O₂ etch the patterned square cross section wells in the polyimide were 3.5-4.5 microns deep. In a control experiment with Kapton tape the wells were also 3.5 microns deep, demonstrating the oxide nanoparticle pattern is performing as an etch mask. The change in depth of the wells from 70±5 to 100±10 nm to 3.5 to 4.5 um demonstrates the nanoparticle photoresist film's capacity to perform as an etch mask with significant contrast.

The following numbered clauses provide additional non-limiting disclosure.
Clause 1. A method of forming a microelectronic structure, the method comprising: providing a substrate having a surface, the surface optionally being coated with one or more additional layers; applying a hardmask composition comprising inorganic nanoparticles and a photoacid generator to the substrate surface or to an outermost surface of the one or more additional layers to form a hardmask layer; exposing the hardmask layer to patterned light to yield exposed and unexposed portions of the hardmask layer; contacting the exposed and unexposed portions of the hardmask layer with a developer to remove the unexposed portions of the hardmask layer to provide a patterned hardmask layer comprising one or more openings; and after removing the unexposed portion of the hardmask layer, annealing the patterned hardmask layer to increase its density to above 65% volume percent solid to provide a dense patterned hardmask layer comprising the one or more openings.
Clause 2. The method of clause 1, wherein the nanoparticles are greater than or equal to 60% by weight of the hardmask layer.
Clause 3. The method of clause 1 or clause 2, wherein the hardmask layer comprises no more than 10% by weight polymeric material.
Clause 4. The method of any one of clauses 1-3, wherein the nanoparticles are nanoparticles of ZrO₂, SiO₂, HfO₂, TiO₂, or Al₂O₃, or a mixture of any combination of ZrO₂, SiO₂, HfO₂, TiO₂, and Al₂O₃ nanoparticles.
Clause 5. The method of any one of clauses 1-4, wherein the dense patterned hardmask layer has a dielectric constant <12 from 10k Hz to 60 GHz.
Clause 6. The method of any one of clauses 1-5, wherein the nanoparticles are amorphous.
Clause 7. The method of any one of clauses 1-5, wherein the nanoparticles are crystalline.
Clause 8. The method of any one of clauses 1-7, wherein the photoacid generator is 1 to 50 weight percent of the hardmask layer.
Clause 9. The method of any one of clauses 1-7, wherein the photoacid generator is zwitterionic.
Clause 10. The method of any one of clauses 1-9, wherein the photoacid generator is or comprises 1-Diazo-2-naphthol-4-sulfonic acid (DNS). 2-diazo-1-naphthol-4-sulfonic acid (2-DNS), 2-diazo-1-naphthol-4-sulfonyl chloride (DNQ-Cl), 4-(1-methyl-1-phenylethyl)-phenyl 3-diazo-3,4-dihydro-4-oxo-1-naphthalenesulfonate (DNQ-Ar), or mixtures thereof.
Clause 11. The method of any one of clauses 1-10, wherein the hardmask composition comprises gamma butyrolactone, ethyl lactate, dimethyl sulfoxide, water, isopropyl alcohol, ethylene glycol, propylene glycol, acetonitrile, cyrene, m-cresol, or mixtures thereof..
Clause 12. The method of any one of clauses 1-11, wherein the developer is aqueous based.
Clause 13. The method of clause 12, wherein the developer is an aqueous 1-10 weight percent Tetramethylammonium hydroxide solution.
Clause 14. The method of clause 13, wherein the developer is or comprises deionized water.
Clause 15. The method of any one of clauses 1-14, wherein the one or more additional layers comprises a dielectric layer.
Clause 16. The method of clause 15, wherein the dielectric layer comprises a glass or a polymer.
Clause 17. The method of clause 16, wherein the polymer is or comprises a polyimide, a benzocyclobutene, or a polybenzoxazoles.
Clause 18. The method of any one of clauses 15-17, comprising etching the dielectric layer through the one or more openings in the dense patterned hardmask layer to pattern the dielectric layer with one or more trenches, vias, or any combination of trenches and vias.
Clause 19. The method of clause 18, wherein the one or more trenches, vias, or any combination of trenches and vias have minimum lateral widths in a plane of the dielectric layer greater than 0.0 microns and less than or equal to 5.0 microns and depths perpendicular to the plane of the dielectric layer greater than or equal to 2.0 microns.
Clause 20. The method of clause 18 or clause 19, comprising filling the one or more trenches, vias, or any combination of trenches and vias with metal.
Clause 21. The method of clause 20, comprising removing the dense patterned hardmask layer before filling the one or more trenches, vias, or any combination of trenches and vias with metal.
Clause 22. The method of clause 20, comprising retaining the dense patterned hardmask layer on the dielectric layer while filling the one or more trenches, vias, or any combination of trenches and vias with metal.
Clause 23. The method of any one of clauses 15-17, comprising: disposing a dielectric layer on the dense patterned hardmask layer; applying a hardmask composition comprising inorganic nanoparticles and a photoacid generator to the dielectric layer on the dense patterned hardmask layer to form a second hardmask layer; exposing the second hardmask layer to patterned light to yield exposed and unexposed portions of the second hardmask layer; contacting the exposed and unexposed portions of the second hardmask layer with a developer to remove the unexposed portions of the second hardmask layer to provide a second patterned hardmask layer comprising one or more openings overlapping the one or more openings in the underlying dense patterned hardmask layer; and after removing the unexposed portion of the second hardmask layer, annealing the second patterned hardmask layer to increase its density to above 65% volume percent solid to provide a second dense patterned hardmask layer comprising the one or more openings overlapping the one or more openings in the underlying dense patterned hardmask layer.
Clause 24. The method of clause 23, comprising etching the second dielectric layer and the underlying dielectric layer through the one or more openings in the dense second patterned hardmask layer and the one or more openings in the underlying dense patterned hardmask layer to pattern the second dielectric layer and the underlying dielectric layer with one or more trenches, vias, or any combination of trenches and vias.
Clause 25. The method of clause 24, comprising filling the one or more trenches, vias, or any combination of trenches and vias with metal.
Clause 26. A semiconductor structure comprising: a semiconductor substrate; a dielectric layer disposed on the semiconductor substrate or on one or more additional layers disposed on the semiconductor substrate; and a dense patterned hardmask layer disposed on the dielectric layer, the hardmask layer comprising greater than or equal to 60% by weight inorganic nanoparticles, having a density greater than or equal to 65% volume percent solid, and comprising one or more openings through which the dielectric layer may be selectively etched.
Clause 27. The semiconductor structure of clause 26, wherein the dense patterned hardmask layer comprises no more than 10% by weight polymeric material.
Clause 28. The semiconductor structure of clause 26 or clause 27, wherein the nanoparticles are nanoparticles of ZrO₂, SiO₂, HfO₂, TiO₂, or Al₂O₃, or a mixture of any combination of ZrO₂, SiO₂, HfO₂, TiO₂, or Al₂O₃ nanoparticles.
Clause 29. The semiconductor structure of any one of clauses 26-28, wherein the dense patterned hardmask layer has a dielectric constant <12 from 10k Hz to 60 GHz.
Clause 30. The semiconductor structure of any one of clauses 26-29, wherein the nanoparticles are amorphous.
Clause 31. The semiconductor structure of any one of clauses 26-29, wherein the nanoparticles are crystalline.
Clause 32. The semiconductor structure of any one of clauses 26-31, wherein the dielectric layer comprises a glass or a polymer.
Clause 33. The semiconductor structure of clause 32, wherein the polymer is or comprises a polyimide, a benzocyclobutene, or a polybenzoxazoles.

This disclosure is illustrative and not limiting. Further modifications will be apparent to one skilled in the art in light of this disclosure and are intended to fall within the scope of the appended claims.

What is claimed is:

1. A method of forming a microelectronic structure, the method comprising:
providing a substrate having a surface, the surface optionally being coated with one or more additional layers;
applying a hardmask composition comprising inorganic nanoparticles and a photoacid generator to the substrate surface or to an outermost surface of the one or more additional layers to form a hardmask layer;
exposing the hardmask layer to patterned light to yield exposed and unexposed portions of the hardmask layer;
contacting the exposed and unexposed portions of the hardmask layer with a developer to remove the unexposed portions of the hardmask layer to provide a patterned hardmask layer comprising one or more openings; and
after removing the unexposed portion of the hardmask layer, annealing the patterned hardmask layer to increase its density to above 65% volume percent solid to provide a dense patterned hardmask layer comprising the one or more openings.

2. The method of claim 1, wherein the nanoparticles are greater than or equal to 60% by weight of the hardmask layer.

3. The method of claim 2, wherein the hardmask layer comprises no more than 10% by weight polymeric material.

4. The method of claim 2, wherein the nanoparticles are nanoparticles of ZrO₂, SiO₂, HfO₂, TiO₂, or Al₂O₃, or a mixture of any combination of ZrO₂, SiO₂, HfO₂, TiO₂, and Al₂O₃ nanoparticles.

5. The method of claim 2, wherein the photoacid generator is 1 to 40 weight percent of the hardmask layer.

6. The method of claim 5, wherein the photoacid generator is zwitterionic.

7. The method of claim 6, wherein the zwitterionic photoacid generator is or comprises 1-Diazo-2-naphthol-4-sulfonic acid (DNS), 2-diazo-1-naphthol-4-sulfonic acid (2-DNS), 2-diazo-1-naphthol-4-sulfonyl chloride (DNQ-Cl), 4-(1-methyl-1-phenylethyl)-phenyl 3-diazo-3,4-dihydro-4-oxo-1-naphthalenesulfonate (DNQ-Ar), or mixtures thereof.

8. The method of claim 2, wherein the hardmask composition comprises gamma butyrolactone, ethyl lactate, dimethyl sulfoxide, water, isopropyl alcohol, ethylene glycol, propylene glycol, acetonitrile, m-cresol, cyrene, propylene carbonate, or mixtures thereof.

9. The method of claim 2, wherein the developer is or comprises deionized water.

10. The method of claim 2, wherein the one or more additional layers comprises a dielectric layer.

11. The method of claim 10, wherein the dielectric is or comprises a glass, a polyimide, a benzocyclobutene, or a polybenzoxazole.

12. The method of claim 10, comprising:
etching the dielectric layer through the one or more openings in the dense patterned hardmask layer to pattern the dielectric layer with one or more trenches, vias, or any combination of trenches and vias;
wherein the one or more trenches, vias, or any combination of trenches and vias have minimum lateral widths in a plane of the dielectric layer greater than 0.0 microns and less than or equal to 5.0 microns and depths perpendicular to the plane of the dielectric layer greater than or equal to 2.0 microns.

13. The method of claim 12, comprising removing the dense patterned hardmask layer before filling the one or more trenches, vias, or any combination of trenches and vias with metal.

14. The method of claim 12, comprising retaining the dense patterned hardmask layer on the dielectric layer while filling the one or more trenches, vias, or any combination of trenches and vias with metal.

15. The method of claim 10, comprising:
disposing a dielectric layer on the dense patterned hardmask layer;
applying a hardmask composition comprising inorganic nanoparticles and a photoacid generator to the dielectric layer on the dense patterned hardmask layer to form a second hardmask layer;
exposing the second hardmask layer to patterned light to yield exposed and unexposed portions of the second hardmask layer;
contacting the exposed and unexposed portions of the second hardmask layer with a developer to remove the unexposed portions of the second hardmask layer to provide a second patterned hardmask layer comprising one or more openings overlapping the one or more openings in the underlying dense patterned hardmask layer;
after removing the unexposed portion of the second hardmask layer, annealing the second patterned hardmask layer to increase its density to above 65% volume percent solid to provide a second dense patterned hardmask layer comprising the one or more openings overlapping the one or more openings in the underlying dense patterned hardmask layer;
etching the second dielectric layer and the underlying dielectric layer through the one or more openings in the dense second patterned hardmask layer and the one or more openings in the underlying dense patterned hardmask layer to pattern the second dielectric layer and the underlying dielectric layer with one or more trenches, vias, or any combination of trenches and vias; and
filling the one or more trenches, vias, or any combination of trenches and vias with metal.

16. A semiconductor structure comprising:
a semiconductor substrate;
a dielectric layer disposed on the semiconductor substrate or on one or more additional layers disposed on the semiconductor substrate; and
a dense patterned hardmask layer disposed on the dielectric layer, the hardmask layer comprising greater than or equal to 60% by weight inorganic nanoparticles, having a density greater than or equal to 65% volume percent solid, and comprising one or more openings through which the dielectric layer may be selectively etched.

17. The semiconductor structure of claim 16, wherein the dense patterned hardmask layer comprises no more than 10% by weight polymeric material.

18. The semiconductor structure of claim 16, wherein the nanoparticles are nanoparticles of ZrO2, SiO2, HfO2, TiO2, or Al2O3, or a mixture of any combination of ZrO2, SiO2, HfO2, TiO2, or Al2O3 nanoparticles.

19. The semiconductor structure of claim 16, wherein the dense patterned hardmask layer has a dielectric constant <12 from 10k Hz to 60 GHz.

20. The semiconductor structure of claim 16, wherein the dielectric is or comprises a glass, a polyimide, a benzocyclobutene, or a polybenzoxazole.
